(19) United States
(12) Patent Application Publication
(10) Pub. No.: US 2006/0023419 A1
(43) Pub. Date: Feb. 2, 2006

(54) Adjusting air duct

(76) Inventors: Min-Che Kao, Taipei City (TW); Andy Ho, Taipei City (TW)

Correspondence Address: BIRCH STEWART KOLASCH & BIRCH, PO BOX 747, FALLS CHURCH, VA, 22040-0747, US

(21) Appl. No.: 10/900,353

(22) Filed: Jul. 28, 2004

(51) Int. Cl. H05K 7/20

(52) U.S. Cl. 361/690

(57) ABSTRACT

An adjusting air duct adopts a novel design so that it is movable according to the location of the heat generating source in a computer host to be aligned with air vents of the side board of the computer host. Therefore external cooling air may be sucked in through fans and channeled to the heat generating source through the air duct to achieve optimal heat dissipation effect.

### FIELD OF THE INVENTION

The present invention relates to an adjusting air duct and particularly to an air duct movable to match air vents of the side board of a computer host according to the location of the heat generating source of the computer host.

### BACKGROUND OF THE INVENTION

The heat generating source of a general computer host such as CPU generates a lot heat during operation. Hence suitable heat dissipation measures must be taken to enable the CPU to function normally without being overheated and damaged.

The conventional radiation device for CPU has a plurality of upright radiation fins mounted onto the CPU and a fan located above the radiation fins. The radiation fins absorb heat from the CPU, and the fan dispels the heat from the radiation fins so that the CPU can maintain a suitable operation temperature.

Due to the processing speed of CPU increases continuously, heat generated by the CPU also increases. Heat dissipation efficiency of the radiation device for the CPU also has to increase to prevent the CPU from overheated or damaged.

The conventional radiation fan is an axial fan which draws air axially and discharges the air at another side. Airflow is directed vertically and results in air turbulence in the computer case. The irregular airflow in the computer case affects air exchange between the air inside and outside the computer case, and reduces the performance of the total heat dissipation system. To remedy this problem, there is a design to install a hood above the CPU. The hood has an outlet to couple with an air duct which is connected to an air vent of the computer case. A fan is installed on a lower side of the hood or abutting the air vent of the computer case to generate forced air exchange between the interior and the exterior of the computer case. The fan can generate a steady airflow in a closed environment, and the airflow speed can increase. Thus an improved heat dissipation effect may be achieved. However, the air duct usually is flexible, and tends to bend and twist in the computer case. As a result, airflow generated by the fan will hit and bump the air duct and form an irregular flow. This causes undesirable airflow in the case.

To overcome the aforesaid air duct problem, there is a technique disclosed in R.O.C. patent publication No. 481286 entitled “Air duct coupling apparatus”. It has an air duct consisting of two opposing tubes that are coupled together. The air duct is anchored on the case through a pair of juxtaposed latch hooks and an elastic latch blade. R.O.C. patent publication No. 537428 entitled “Computer air channeling apparatus” discloses an air duct consisting of a first tube and a second tube that are integrally formed and connected in a normal manner. The first tube has one end anchored on the heat generating source, and the second tube has one end anchored on the air vent of the computer case through a fastening element. R.O.C. patent publication No. 562393 entitled “Screwless air duct anchoring apparatus” discloses an air duct which has one side coupled with an elbow tube for housing a fan. The air duct is straddled the air discharge vent of the computer host through a plurality of hook pawls and latch hooks. All of aforesaid references have an air duct to bridge the heat generating source and the air vent of the computer case to form a regular airflow in the air duct so that air exchange speed between the interior and the exterior of the computer case may increase to improve heat dissipation.

However, the installation location of the heat generating source (such as CPU) on the main board varies among different vendors. One type of air duct cannot fit all of them equally well. In some occasions, the air duct cannot be aligned correctly with the air vent and results in not desirable heat dissipation effect. Moreover, different vendors and brands have different element arrangement in the computer case. The same air duct structure could be not fitting in some interior space or cause conflict with the element installation locations.

### SUMMARY OF THE INVENTION

The primary object of the present invention is to solve the aforesaid disadvantages. The present invention provides an adjusting air duct that is adjustable according to different installation locations of the heat generating source on the main board so that the air duct may be always aligned with the air vent of the computer case to avoid the problem of failing to suck in the external cooling air caused by wrong alignment of the air duct and the air vent resulting from change of heat generating source location.

To achieve the foregoing object, the adjusting air duct according to the invention includes an air duct assembly which consists of a first duct and a second duct that are pivotally coupled through a first coupling means to adjust their relative positions, and an adjusting member to pivotally couple with the second duct through a second coupling means to adjust their relative positions so that when the installation location of the heat generating source in the computer case is changed the elements set forth above may be adjusted through the first and the second coupling means to align the ventilation opening of the air duct with the air vent of the computer case to achieve optimal heat dissipation effect.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic view of the present invention in use.

FIG. 2 is an exploded view of the present invention.

FIGS. 3A, 3B and 3C are schematic views of the adjusting member and the second duct in adjustment conditions.

FIGS. 4A and 4B are schematic views of the first duct and the second duct in adjustment conditions.

FIG. 5 is a schematic view of the airflow according to the present invention.

### DETAILED DESCRIPTION OF THE PREFERRED EMBODIMENT

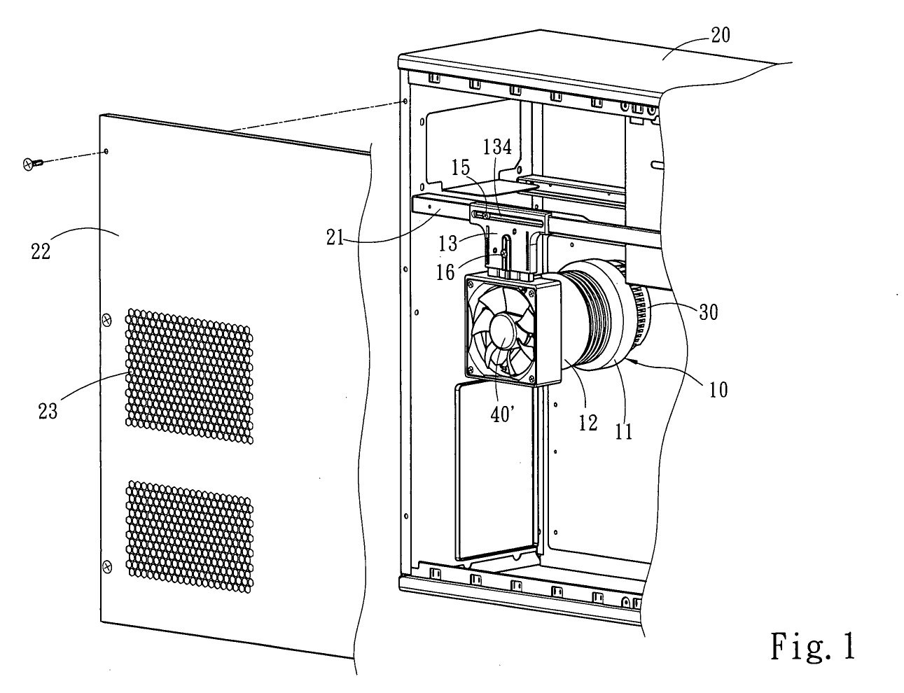

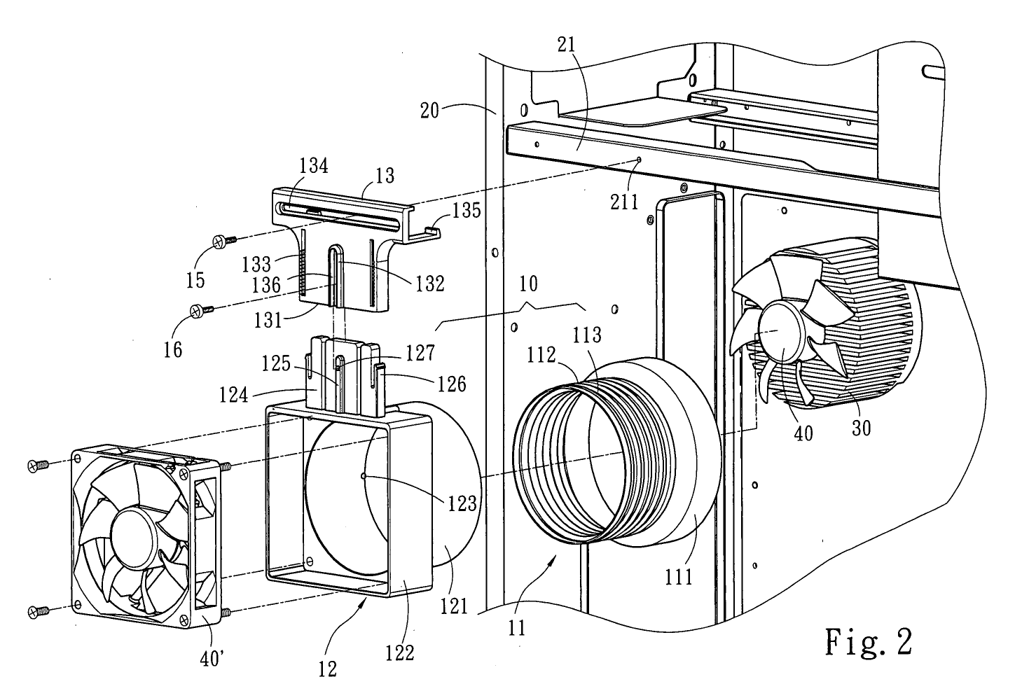

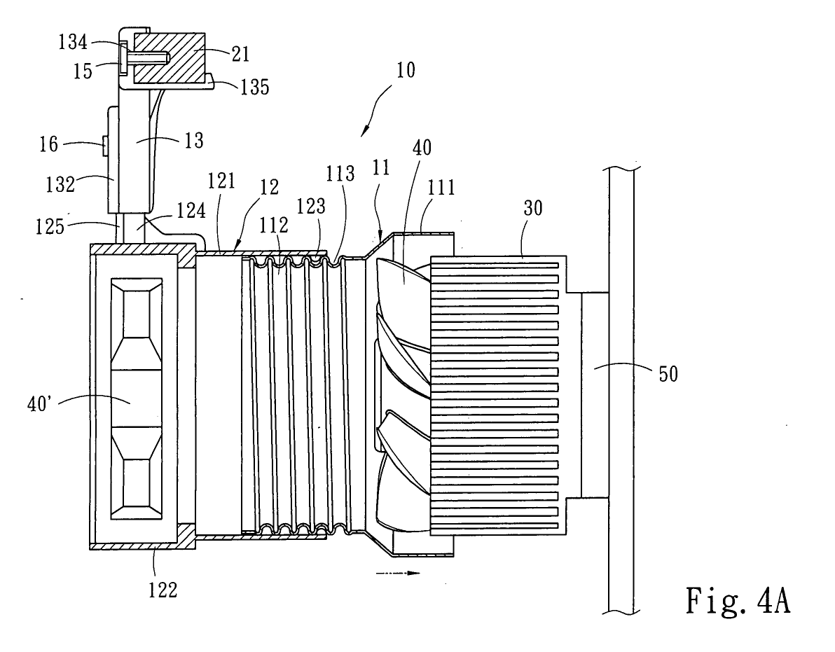

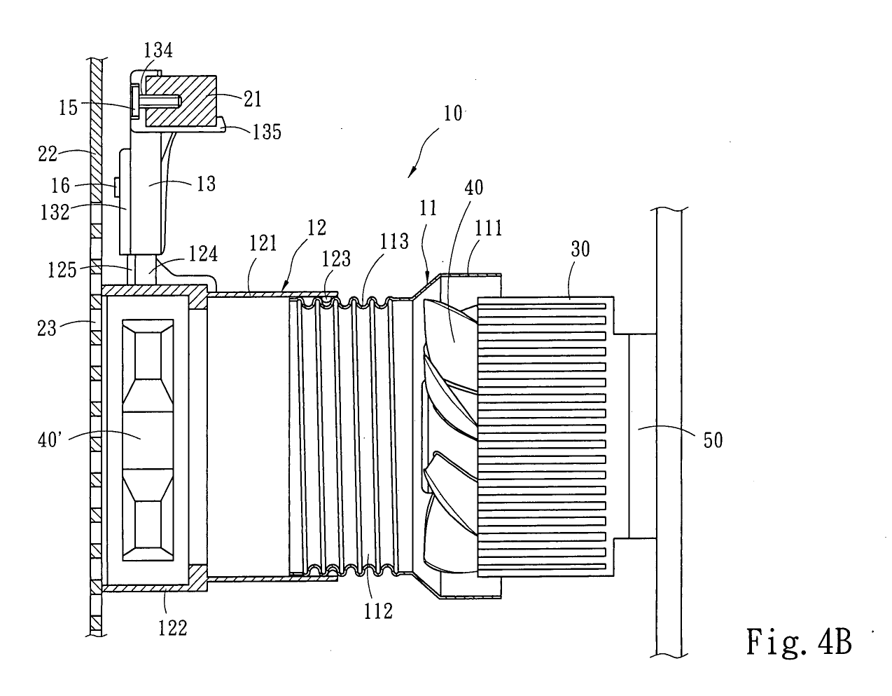

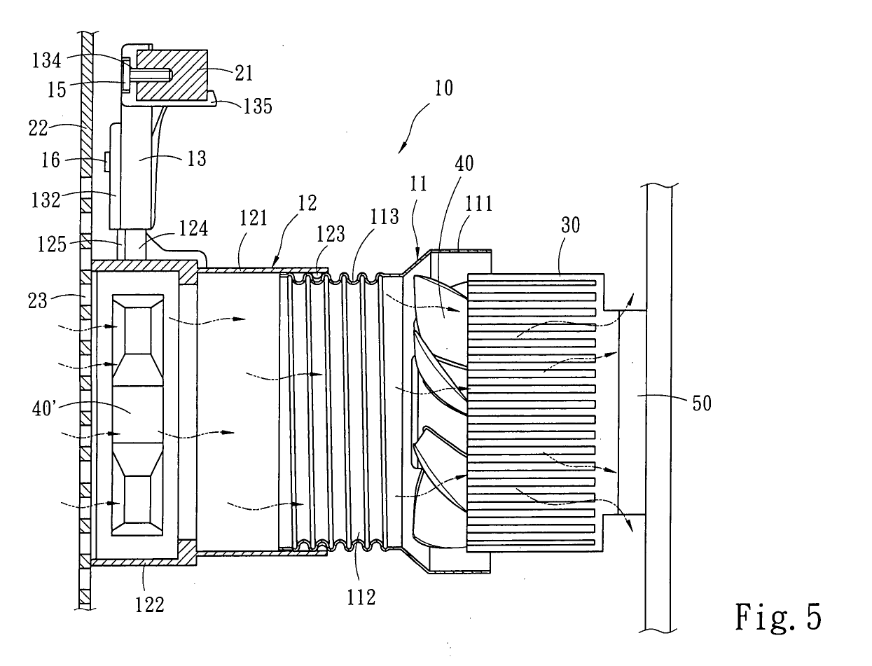

Please referring to FIGS. 1 and 2, the adjusting air duct according to the present invention includes an air duct assembly 10 located between radiation fins 30 mounted onto a heat generating source (such as a CPU 50, referring to FIG. 4A), a first fan 40 and air vents 23 of a side board 22 of a computer case 20. The air duct assembly 10 has a ventilation opening 122 on one end to hold a second fan 40′. There is an adjusting member 13 located above the ventilation opening. The adjusting member 13 has an elongate fastening slot 134 and may be slid on a sliding track 21 and fastened thereon through a fastening element 15 to a fastening hole 211 formed on the sliding track 21. The first fan 40 and second fan 40′ can suck external cooling air through the air vents 23 and the air duct assembly 10 to blow the radiation fins 30 to reduce the temperature of the CPU 50 (referring to FIG. 5).

Referring to FIG. 2, the air duct assembly 10 includes a first duct 11 and a second duct 12. The first duct 11 is located on the radiation fins 30 and the first fan 40. The second duct 12 is pivotally coupled with the first duct 11 through a first coupling means which adjusts the relative position of the first duct 11 and the second duct 12.

The first coupling means includes an annular member 111 formed on the first duct 11 to cover the radiation fins 30 and a tube 112 extending from the center of the annular member 111. The second duct 12 has a sleeve 121 to couple with the tube 112 and the ventilation opening 122 extended from the sleeve 121. The tube 112 has a plurality of helical grooves 113 formed on the outer wall. The sleeve 121 has a bulged element 123 on the inner wall corresponding to and engageable with the helical grooves 113 to couple the first duct 11 and the second duct 12.

The adjusting member 13 is pivotally coupled with the second duct 12 through the second coupling means to generate a relative movement between the adjusting member 13 and the second duct 12. The second coupling means includes a latch member 124 located on one end of the ventilation opening 122. The latch member 124 has a strut 125 in the middle portion and two latch arms 126 on two sides. The adjusting member 13 has a housing compartment 131 to hold the latch member 124 that has a trough 132 matching the strut 125 and teeth racks 133 matching the latch arms 126. The latch member 124 may be inserted into the housing compartment 131 with the strut 125 wedging into the trough 132 and the latch arms 126 engaging with the teeth racks 133 to couple the second duct 12 with the adjusting member 13. The adjusting member 13 further has a pair of hooks 135 to couple on the sliding track 21 of the computer case 20 to brace the air duct assembly 10 without sinking under its own weight.

In addition, the strut 125 has an aperture 127 and the trough 132 has a slot 136 that may be coupled by a fastening element 16 to increase the coupling strength between the adjusting member 13 and the latch member 124.

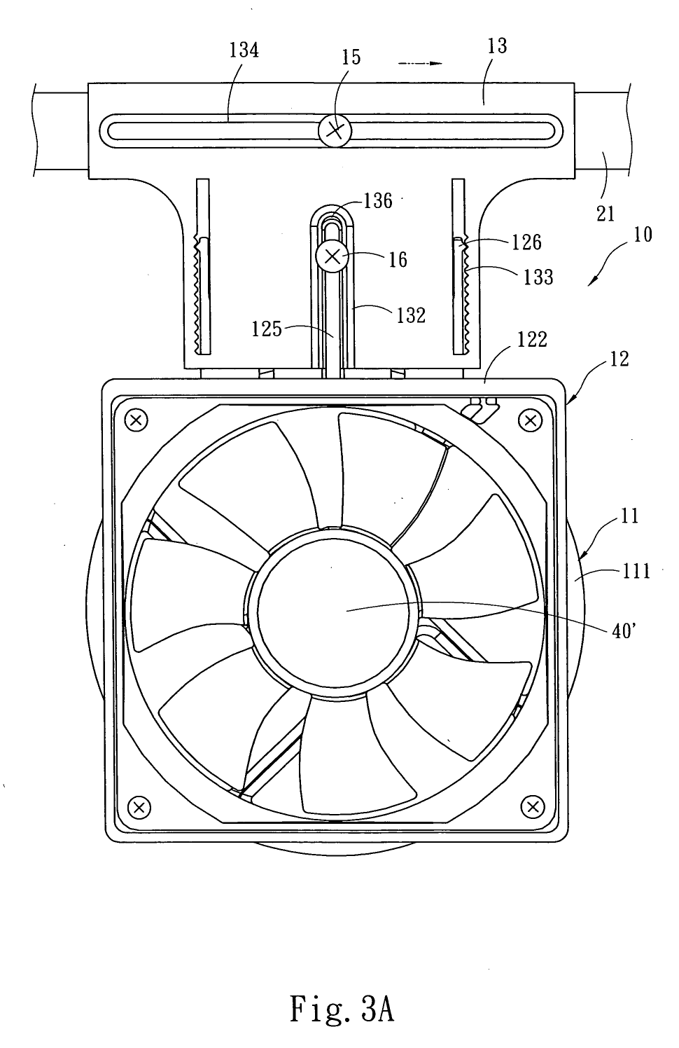

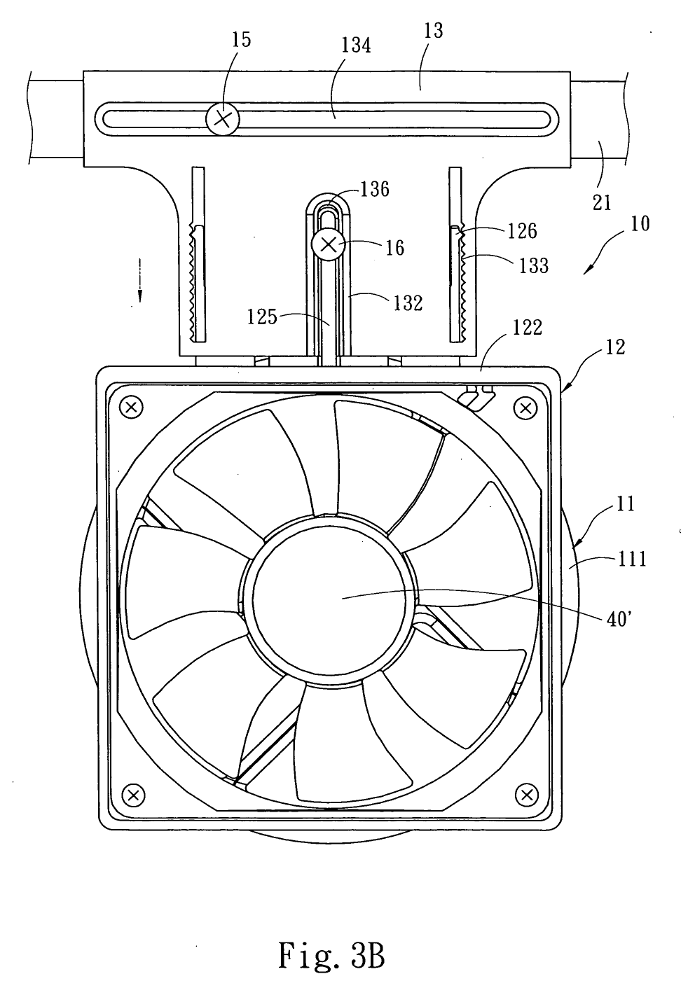

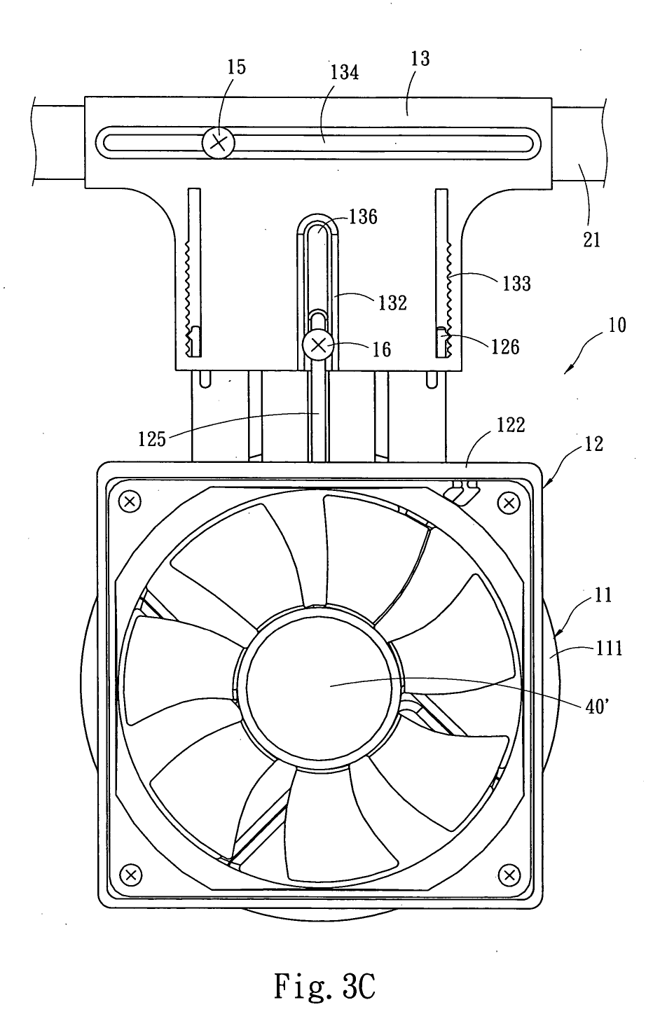

Referring to FIGS. 3A, 3B and 3C, when in use the adjusting member 13 may be moved horizontally on the sliding track 21 to a desired location, then a fastening element 15 may be inserted through the fastening slot 134 to engage with a selected fastening hole 211 of the sliding track 21. Through the second coupling means, the latch member 124 may be moved outwards from the housing compartment 131 to move the latch arms 126 on the teeth racks 133 until reaching a desired location to latch the latch arms 126 on the teeth racks 133. Therefore the relative position of the second duct 12 and the adjusting member 13 may be adjusted.

Refer to FIGS. 4A and 4B for the movement of the first duct and the second duct. Through the first coupling means, the second duct 12 may be moved outwards to allow the bulged element 123 to move from one the helical groove 113 of the tube 112 to another helical groove to adjust the relative position of the first duct 11 and the second duct 12.

What is claimed is:

1. An adjusting air duct having one end coupling with radiation fins mounted on a heat generating source and a first fan and other end corresponding to air vents of a computer case, comprising:
an air duct assembly including a first duct and a second duct, the first duct being coupled with the radiation fins, the second duct being pivotally coupled with the first duct through a first coupling means for forming a relative movement with the first duct; and
an adjusting member coupling with the second duct through a second coupling means for generating a relative movement with the second duct, the adjusting member having a fastening slot and being slidable on and fastenable to a sliding track of the computer case;
wherein the relative movements between the first duct and the second duct, and between the second duct and the adjusting member are adjustable through the first coupling means and the second coupling means according to different locations of the heat generating source in the computer case to align the air duct assembly with the air vents of the computer case.

2. The adjusting air duct of claim 1, wherein the first duct includes an annular member to cover the radiation fins and a tube extending from the center of the annular member, the second duct having a sleeve to couple with the tube and a ventilation opening extended from one end of the sleeve, the first coupling means including a plurality of helical grooves formed on an outer wall of the tube and a bulged element on an inner wall of the sleeve corresponding to and engageable with the helical grooves.

3. The adjusting air duct of claim 2, wherein the ventilation opening houses a second fan.

4. The adjusting air duct of claim 2, wherein the second coupling means includes a latch member located on one end of the ventilation opening, the latch member having a strut in a middle portion and two latch arms on two sides, the adjusting member having a housing compartment to hold the latch member, the housing compartment having a trough matching the strut and teeth racks matching the latch arms such that the latch member is insertable into the housing compartment with the strut wedging into the trough and the latch arms latching on the teeth racks.

5. The adjusting air duct of claim 4, wherein the strut has an aperture, the trough having a slot to receive a fastening element to engage with the aperture.

6. The adjusting air duct of claim 1, wherein the adjusting member has a pair of hooks to couple on the sliding track of the computer case.
